(19) United States
(12) Patent Application Publication
(10) Pub. No.: US 2025/0016989 A1
(43) Pub. Date: Jan. 9, 2025

(54) SEMICONDUCTOR STRUCTURE AND MANUFACTURING METHOD THEREFOR

(71) Applicant: ICLEAGUE TECHNOLOGY CO., LTD., Jiaxing, Zhejiang (CN)

(72) Inventors: Wenyu HUA, Jiaxing (CN); Zhi ZHANG, Jiaxing (CN)

(73) Assignee: ICLEAGUE TECHNOLOGY CO., LTD., Jiaxing, Zhejiang (CN)

(21) Appl. No.: 18/577,386

(22) PCT Filed: Mar. 7, 2022
(86) PCT No.: PCT/CN2022/079583

§ 371 Date: Jan. 8, 2024

(30) Foreign Application Priority Data
Jan. 27, 2022 (CN) 202210101497.0

(51) Int. Cl. H10B 12/00

(52) U.S. Cl. CPC H10B 12/482; H10B 12/02

(57) ABSTRACT

Disclosed are a semiconductor structure and a manufacturing method which includes providing a substrate; forming a first recessed area from a first surface of the substrate, wherein at least two protruding structures are reserved in the first recessed area, and there are at least some of non-overlapping areas in the projections of any two adjacent protruding structures in the direction perpendicular to the extending direction of the protruding structures; filling the first recessed area with an insulating material; thinning from a second surface of the substrate until the insulating material is exposed to the second surface protruding structures from the second surface to form a second recessed area; filling the second recessed area with a conductive material to form bit lines; and at surface positions of the bit lines corresponding to the non-overlapping areas, forming bit line lead-out structures.

### CROSS-REFERENCE TO RELATED APPLICATION

The application is based on and claims priority to Chinese Patent Application No. 202210101497.0, filed on, Jan. 27, 2022, entitled “Semiconductor Structure and Method for Manufacturing Same”, the disclosure of which is hereby incorporated by reference in its entirety.

### TECHNICAL FIELD

The disclosure relates to the technical field of semiconductors, and relates to but is not limited to a semiconductor structure and a method for manufacturing the same.

### BACKGROUND

A semiconductor memory can use an array of transistors to control the charging and discharging of memory capacitors to realize data access. In the semiconductor memory, a drain (or a source) of each of the transistors is electrically connected with a bit line. After the bit lines are formed on the substrate, bit line lead-out structures need to be formed on the bit lines, such that the bit lines are electrically connected with the external control circuit through the bit line lead-out structures.

However, with the increasingly integration of semiconductor devices, the distance between bit lines is shrinking, which leads to the shrinking distance between bit line lead-out structures. This leads to the interconnection between the adjacent bit line lead-out structures, and thus leads to short circuit phenomenon, even the failure of the semiconductor devices. How to reduce the short circuit phenomenon between the adjacent bit line lead-out structures has become an urgent problem to be solved.

### SUMMARY

In view of this, embodiments of the disclosure provide a semiconductor structure and a method for manufacturing the same.

In the first aspect, the embodiment of the disclosure provides a method for manufacturing a semiconductor structure, which includes the following operations.

A substrate is provided.

A first concave area is formed from a first surface of the substrate, and at least two strips of convex structures are retained in the first concave area. Projections of two adjacent strips of the at least two strips of convex structures along a direction perpendicular to an extension direction of the convex structures have at least a part non-overlapping areas.

The first concave area is filled with an insulating material to form a dielectric layer.

The substrate is thinned from a second surface of the substrate until the dielectric layer is exposed on the second surface. The second surface is a back surface of the first surface.

Each of the convex structures is partially removed from the second surface to form a second concave area.

A conductive material is filled in the second concave area to form a bit line.

A bit line lead-out structure connected with the bit line is formed at a position corresponding to the non-overlapping area on a surface of the bit line.

In some embodiments, forming a first concave area from a first surface of the substrate in which at least two strips of convex structures are retained in the first concave area includes the following operations.

A plurality of first barrier structures are formed on the first surface of the substrate.

A part of the substrate not shielded by the first barrier structures is etched to form the first concave area. A part of the substrate shielded by the first barrier structures is retained as the at least two strips of convex structures.

In some embodiments, forming a plurality of first barrier structures on the first surface of the substrate includes the following operations.

A plurality of second barrier structures with rectangular annular shape are formed on the first surface of the substrate.

The plurality of second barrier structures are covered by a first mask layer to shield at least partial area of each of the plurality of second barrier structures. At least two opposite sides of each of the plurality of second barrier structures have unshielded areas.

Areas of the plurality of second barrier structures unshielded by the first mask layer are etched.

The first mask layer is removed. Each of the plurality of second barrier structures not etched includes two of the first barrier structures.

In some embodiments, the two first barrier structures included in each of the plurality of second barrier structures not etched are centrosymmetric with respect to a center of the second barrier structure.

In some embodiments, forming a plurality of second barrier structures with rectangular annular shape on the first surface of the substrate includes the following operations.

A plurality of second mask structures with rectangular shape are formed on the first surface of the substrate.

A second barrier structure surrounding each of the plurality of second mask structures is formed.

In some embodiments, forming a plurality of second mask structures with rectangular shape on the first surface of the substrate includes the following operations.

The first surface of the substrate is covered by a second mask layer.

A photoresist layer with rectangular shapes is formed on the second mask layer.

The second mask layer in an area uncovered by the photoresist layer is removed. The photoresist layer is removed. The second mask layer that has not been removed forms the second mask structures.

In some embodiments, before thinning the substrate from a second surface of the substrate, the method further includes the following operations.

A carrier wafer is provided.

The first surface of the substrate is bonded on the carrier wafer.

The substrate is flipped to make the second surface vertically upward.

In the second aspect, the embodiments of the disclosure provides a semiconductor structure, which includes a substrate, a first concave area, a dielectric layer, second concave areas, bit lines and bit line lead-out structures.

The first concave area is located on a first surface of the substrate. At least two strips of convex structures are retained in the first concave area, and projections of two adjacent strips of the at least two strips of convex structures along a direction perpendicular to an extension direction of the convex structures have at least a part non-overlapping areas.

The dielectric layer is located in the first concave area.

The second concave areas are located on a second surface of the substrate and in the dielectric layer.

Each of the bit lines is located in a corresponding one of the second concave areas and composed of a conductive material.

Each of the bit line lead-out structures is located on a surface of a corresponding one of the bit lines corresponding to the non-overlapping area and is connected with the bit line.

In some embodiments, each of the bit line lead-out structures has a third surface and a fourth surface opposite to each other. The third surface is connected with the corresponding bit line. An area of the fourth surface is larger than an area of the third surface.

In some embodiments, two adjacent ones of the bit lines are centrosymmetric.

In the embodiments of the disclosure, the bit line lead-out structures are arranged in the non-overlapping areas of two adjacent ones of the bit lines along the extending direction of the bit lines, so that a window distance of two adjacent ones of the bit line lead-out structures is increased effectively. Therefore, it is difficult to short-circuit between the two adjacent ones of the bit line lead-out structures, and the bit line lead-out structures are formed in the peripheral area of a transistor array, which improves an effective utilization rate of the peripheral area and improves performance of the device without affecting the space used by the transistor array.

### BRIEF DESCRIPTION OF THE DRAWINGS

FIG. 1 is a cross-sectional view of a substrate where bit lines are to be formed in a method for manufacturing a semiconductor structure provided in some embodiments.

FIG. 2 is a cross-sectional view of a substrate bonded with a carrier wafer in a method for manufacturing a semiconductor structure provided in some embodiments.

FIG. 3A is a top view of a substrate after thinning in a method for manufacturing a semiconductor structure provided in some embodiments.

FIG. 3B is a cross-sectional view of a substrate after thinning in a method for manufacturing a semiconductor structure provided in some embodiments.

FIG. 4A is a top view of a structure after a layer of bit line material is formed in a method for manufacturing a semiconductor structure provided in some embodiments.

FIG. 4B is a cross-sectional view of a structure after a layer of bit line material is formed in a method for manufacturing a semiconductor structure provided in some embodiments.

FIG. 5A is a top view of a structure after bit lines are formed in a method for manufacturing a semiconductor structure provided in some embodiments.

FIG. 5B is a cross-sectional view of a structure after bit lines are formed in a method for manufacturing a semiconductor structure provided in some embodiments.

FIG. 6A is a top view of a structure after bit line lead-out structures are formed in some embodiments.

FIG. 6B is a cross-sectional view of a structure after bit line lead-out structures are formed in some embodiments.

FIG. 7 is a flowchart showing a method for manufacturing a semiconductor structure provided by an embodiment of the disclosure.

FIG. 8 is a schematic structural diagram of a substrate provided by an embodiment of the disclosure.

FIG. 9A is a top view of a substrate after convex structures are formed in a method for manufacturing a semiconductor structure provided by an embodiment of the disclosure.

FIG. 9B is a cross-sectional view of the substrate after convex structures are formed in a method for manufacturing a semiconductor structure provided by the embodiment of the disclosure.

FIG. 10A is a top view of a structure after a dielectric layer is formed in a method for manufacturing a semiconductor structure provided by an embodiment of the disclosure.

FIG. 10B is a cross-sectional view of the structure after a dielectric layer is formed in a method for manufacturing a semiconductor structure provided by the embodiment of the disclosure.

FIG. 11A is a top view of a structure after the substrate is thinned in a method for manufacturing a semiconductor structure provided by an embodiment of the disclosure.

FIG. 11B is a cross-sectional view of a structure after the substrate is thinned in a method for manufacturing a semiconductor structure provided by the embodiment of the disclosure.

FIG. 12A is a top view of a structure after second concave areas are formed in a method for manufacturing a semiconductor structure provided by an embodiment of the disclosure.

FIG. 12B is a cross-sectional view of the structure after second concave areas are formed in a method for manufacturing a semiconductor structure provided by the embodiment of the disclosure.

FIG. 13A is a top view of a structure after bit lines are formed in a method for manufacturing a semiconductor structure provided by an embodiment of the disclosure.

FIG. 13B is a cross-sectional view of the structure after bit lines are formed in a method for manufacturing a semiconductor structure provided by the embodiment of the disclosure.

FIG. 13C is a cross-sectional view of a structure after bit lines are formed in another method for manufacturing a semiconductor structure provided by an embodiment of the disclosure.

FIG. 14A is a top view of a semiconductor structure provided by an embodiment of the disclosure.

FIG. 14B is a cross-sectional view of the semiconductor structure provided by the embodiment of the disclosure.

FIG. 14C is a cross-sectional view of another semiconductor structure provided by an embodiment of the disclosure.

FIG. 15A is a top view of a structure after first barrier structures are formed in a method for manufacturing a semiconductor structure provided by an embodiment of the disclosure.

FIG. 15B is a cross-sectional view of the structure after first barrier structures are formed in a method for manufacturing a semiconductor structure provided by an embodiment of the disclosure.

FIG. 16A is a top view of a structure after second barrier structures are formed in a method for manufacturing a semiconductor structure provided by an embodiment of the disclosure.

FIG. 16B is a cross-sectional view of the structure after second barrier structures are formed in a method for manufacturing a semiconductor structure provided by the embodiment of the disclosure.

FIG. 17A is a top view of a structure after the second barrier structures are covered by a first mask layer in a method for manufacturing a semiconductor structure provided by an embodiment of the disclosure.

FIG. 17B is a cross-sectional view of the structure after the second barrier structures are covered by the first mask layer in a method for manufacturing a semiconductor structure provided by the embodiment of the disclosure.

FIG. 18A is a top view of a structure after second mask structures are formed in a method for manufacturing a semiconductor structure provided by an embodiment of the disclosure.

FIG. 18B is a cross-sectional view of the structure after second mask structures are formed in a method for manufacturing a semiconductor structure provided by the embodiment of the disclosure.

FIG. 19A is a top view of a structure after a second barrier structure surrounding each of the second mask structures is formed in a method for manufacturing a semiconductor structure provided by an embodiment of the disclosure.

FIG. 19B is a cross-sectional view of the structure after the second barrier structure surrounding each of the second mask structures is formed in a method for manufacturing a semiconductor structure provided by the embodiment of the disclosure.

FIG. 20A is a top view of a structure after a photoresist layer is formed on a second mask layer in a method for manufacturing a semiconductor structure provided by an embodiment of the disclosure.

FIG. 20B is a cross-sectional view of a structure after the photoresist layer is formed on the second mask layer in a method for manufacturing a semiconductor structure provided by the embodiment of the disclosure.

FIG. 21A is a top view of a structure after second mask structures are formed in a method for manufacturing a semiconductor structure provided by an embodiment of the disclosure.

FIG. 21B is a cross-sectional view of the structure after second mask structures are formed in a method for manufacturing a semiconductor structure provided by the embodiment of the disclosure.

FIG. 22A is a top view of a structure after bit lines are formed in a method for manufacturing a semiconductor structure provided by an embodiment of the disclosure.

FIG. 22B is a top view of a structure after bit lines are formed in another method for manufacturing a semiconductor structure provided by an embodiment of the disclosure.

FIG. 22C is a top view of a structure after bit lines are formed in yet another method for manufacturing a semiconductor structure provided by an embodiment of the disclosure.

FIGS. 23A-23D are schematic process diagrams during a method for manufacturing a semiconductor structure provided in some embodiments.

FIGS. 24A-24D are schematic process diagrams during a method for manufacturing a semiconductor structure provided by the embodiments of the disclosure.

Substrate: 100; Carrier wafer: 101; First surface: S1; Second surface: S2; Third surface: S3; Fourth surface: S4; Convex structure: 301; Insulating layer: 302; Bit line: 303; Dielectric layer: 304; Bit line lead-out structure 305; First concave area: 401; Second concave area: 402; First barrier structure: 403; Second barrier structure: 404; First mask layer: 405; Second mask structure: 406; Photoresist layer: 407; Second mask layer: 408.

### DETAILED DESCRIPTION

In order to facilitate understanding of the disclosure, exemplary embodiments of the disclosure will be described in more detail below with reference to the related drawings. Although the exemplary embodiments of the disclosure are shown in the drawings, it should be understood that the disclosure may be implemented in various forms and should not be limited to the specific embodiments set forth herein. On the contrary; the embodiments are provided to enable a more thorough understanding of the disclosure and to fully convey the scope of the disclosure to those skilled in the art.

In the description below, numerous specific details are given for more thorough understanding of the disclosure. However, it will be apparent to those skilled in the art that the disclosure may be practiced without one or more of these details. In some embodiments, some technical features well known in the art are not described in order to avoid confusion with the disclosure, that is, not all features of the actual embodiments may be described herein and well-known functions and structures are not described in detail.

In general, terms can be understood, at least in part, from their use in the context. For example, depending at least in part on the context, the term “one or more” as used herein may be used to describe any feature, structure, or characteristic in a singular sense, or may be used to describe a combination of features, structures, or characteristics in a plural sense. Similarly, terms such as “a/an” or “said/the” may likewise be understood as conveying singular usage or conveying plural usage, depending at least in part on the context. Additionally, the term “based on” may be understood as a set of factors not necessarily intended to convey an exclusive, and may alternatively allow an existence of additional factors that are not necessarily explicitly described, also depending at least in part on context.

The terminology used herein is intended to describe specific embodiments only and is not to be a limitation of the disclosure unless otherwise defined. As used herein, the singular forms of “a/an”, “one” and “said/the” are also intended to include the plural forms, unless the context clearly indicates otherwise. It should also be understood that the terms “compose” and/or “comprise/include”, when used in this specification, determine the presence of the stated features, integers, steps, operations, elements and/or components, but do not exclude the presence or addition of one or more other features, integers, steps, operations, elements, components and/or groups. When used herein, the term “and/or” includes any of the listed items and all combinations thereof.

In order to fully understand the disclosure, detailed operations and detailed structures are presented in the following description in order to explain the technical solution of the disclosure. Preferred embodiments of the disclosure are described in detail below. However, the disclosure may have other embodiments except these detailed descriptions.

In some embodiments, in a process for manufacturing a semiconductor memory, bit lines of transistors may be formed by the following operations.

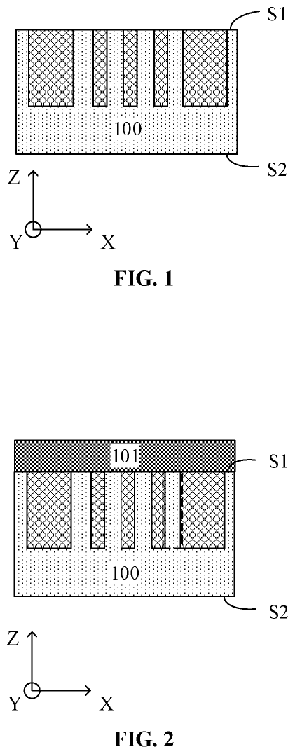

As shown in FIG. 1, a substrate 100 on which bit lines are to be formed is provided. A thickness direction of the substrate 100 or a direction perpendicular to the surface of the substrate 100 is defined as the Z direction. A top surface and a bottom surface perpendicular to the Z direction of the substrate 100 are defined as the first surface S1 and the second surface S2 opposite each other, respectively. An X direction and a Y direction intersecting each other are defined on the first surface S1 or the second surface S2 perpendicular to the Z direction. There may be a transistor array on the substrate. The transistor array may include at least one transistor. In some embodiments, the transistor array may be connected with memory capacitors. One transistor may be connected with one memory capacitor. A side close to the memory capacitors is the second surface S2. The memory capacitors and the bit lines are respectively located on the opposite sides, that is, the bit lines are formed on the first surface S1 of the substrate.

As shown in FIG. 2, a carrier wafer 101 is provided. The carrier wafer 101 is bonded to the first surface S1 of the substrate 100 on which the bit lines are to be formed. After bonding, the carrier wafer 101 and the substrate 100 are flipped to make the second surface S2 vertically upward.

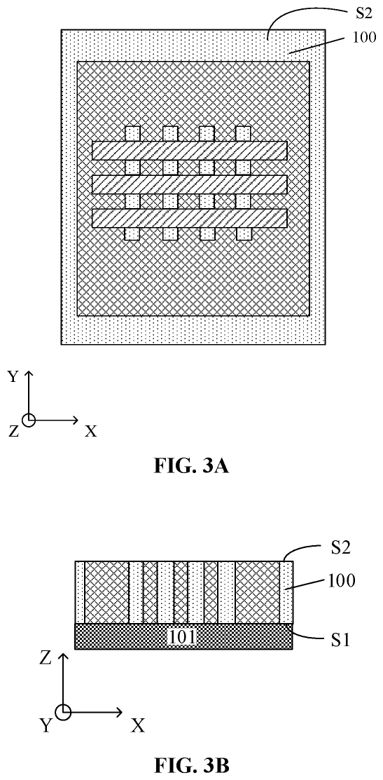

The substrate is thinned from the second surface S2, as shown in FIG. 3A and FIG. 3B. FIG. 3A is a top view of the thinned substrate from the surface S2, and FIG. 3B is a cross-sectional view along the X direction of FIG. 3A. A manner for thinning includes, but is not limited to, dry etching, wet etching, and CMP or the like. The substrate is thinned until the insulating material in the substrate 100 is exposed.

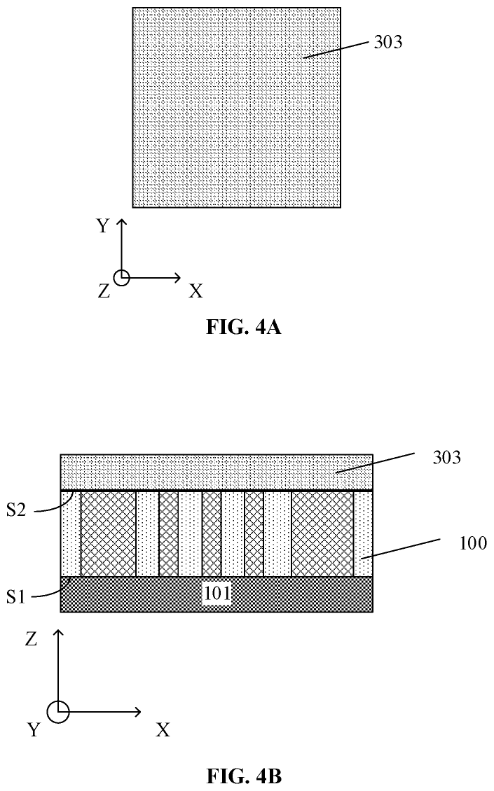

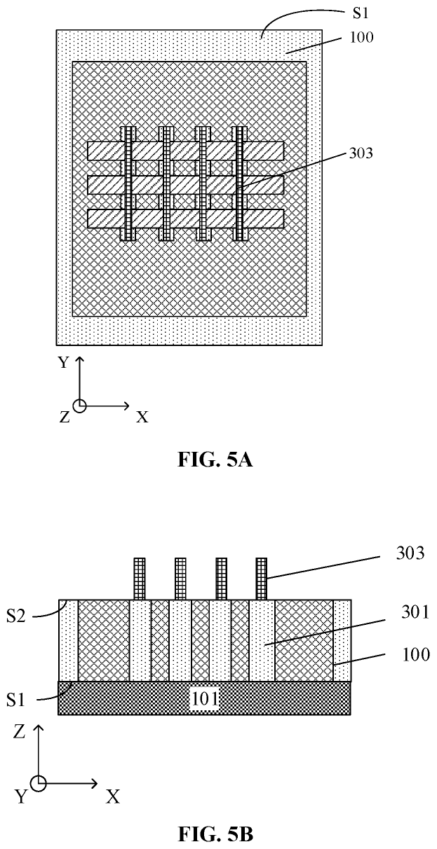

As shown in FIG. 4A and FIG. 4B, FIG. 4A is a top view of the structure after a bit line metal material is deposited from the surface S2, and FIG. 4B is a cross-sectional view along the X direction of FIG. 4A. Depositing the bit line metal material 303 includes sequentially depositing one or more layer of a doped polysilicon layer, a metal silicide layer (e.g. titanium silicide), and a metal tungsten layer on the second surface S2 of the transistor array. Then, a semiconductor structure as shown in FIG. 5A and FIG. 5B is formed by a self-aligned double patterning (SADP) technique. FIG. 5A is a top view of a structure after the bit lines are formed from the S2 surface, and FIG. 5B is a cross-sectional view along the X direction of FIG. 5A. The bit lines are located on the second surface S2 of the substrate 100.

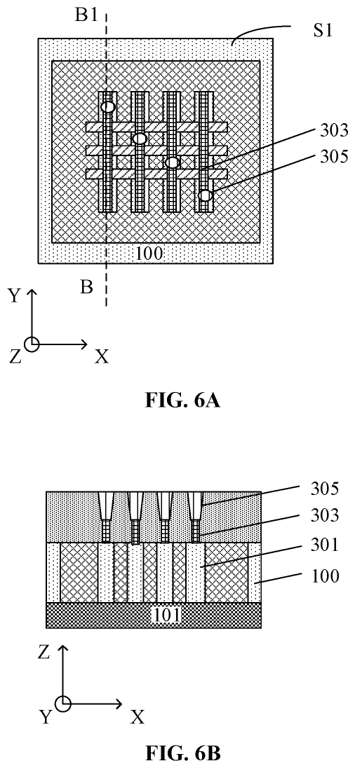

The bit line lead-out structures 305 as shown in FIG. 6A and FIG. 6B are formed on the bit lines 303. FIG. 6A is a top view from the second surface S2 toward the first surface S1, and FIG. 6B is a cross-sectional view from the X direction of FIG. 6A. It can be seen that because a spacing between the bit lines is too small, a window distance of the bit line lead-out structures 305 is too small, which may lead to short circuit between the bit line lead-out structures 305, and thus cause the failure of the semiconductor device.

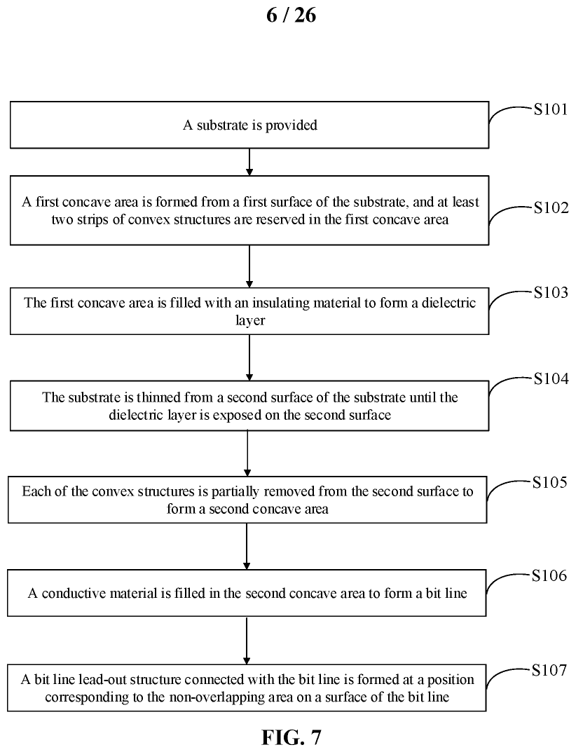

The embodiments of the disclosure provide a method for manufacturing a semiconductor structure, which includes the following operations as shown in FIG. 7.

In S101, a substrate is provided.

In S102, a first concave area 401 is formed from a first surface of the substrate, in which at least two strips of convex structures 301 are retained in the first concave area. Projections of two adjacent strips of the at least two strips of convex structures 301 along a direction perpendicular to an extension direction of the convex structures 301 have at least a part non-overlapping areas.

In S103, the first concave area 401 is filled with an insulating material to form a dielectric layer 304.

In S104, the substrate 100 is thinned from a second surface S2 until the dielectric layer 304 is exposed on the second surface S2. The second surface S2 is a back surface of the first surface S1.

In S105, each of the convex structures 301 is partially removed from the second surface S2 to form a second concave area 402.

In S106, a conductive material is filled in the second concave area 402 to form a bit line 303.

In S107, a bit line lead-out structure 305 is formed at a position corresponding to the non-overlapping area on a surface of the bit line 303 and connected with the bit line 303.

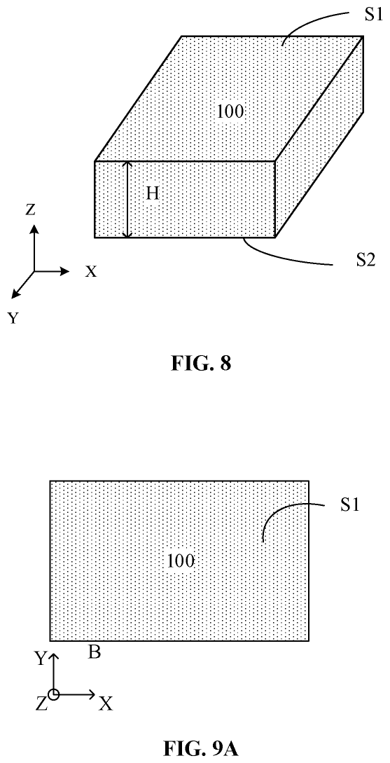

In the above operation S101, the substrate 100 as shown in FIG. 8 is provided. The surface of the substrate 100 is any surface perpendicular to the thickness direction of the substrate. The thickness direction of the substrate or a direction perpendicular to the surface of the substrate is defined as the Z direction. The thickness of the substrate along the Z direction is H. A top surface or a bottom surface perpendicular to the Z direction of the substrate 100 are defined as the first surface S1 and the second surface S2 opposite each other, respectively. The X direction and the Y direction intersecting each other are defined on the first surface S1 or the second surface S2 perpendicular to the Z direction. In some embodiments, the X direction may be a direction along which gates of transistors form and the Y direction may be a direction along which the bit lines of the transistors form. The semiconductor substrate may include a substrate of P-type semiconductor material, such as silicon (Si) substrate or germanium (Ge) substrate, etc., a substrate of N-type semiconductor material, such as indium phosphide (InP) substrate, a substrate of composite semiconductor material, such as silicon germanium (SiGe) substrate, etc., a substrate of silicon on insulator (SOI) and a substrate of germanium on insulator (GeOI), etc. In addition, the substrate in the embodiments of the disclosure may also be a substrate that has formed a part of device structures for example, a substrate that has a transistor array or some wiring, which is not limited herein.

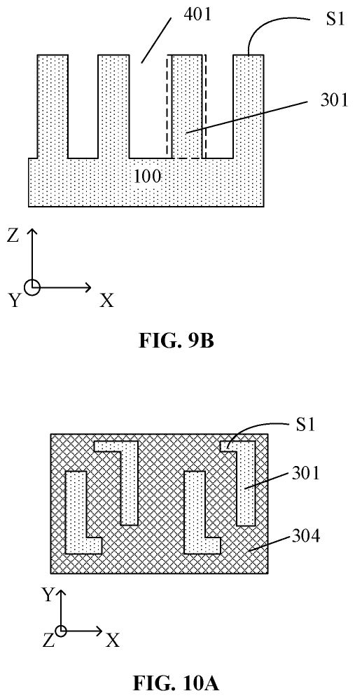

In the above operation S102, the substrate is processed from the first surface S1 of the substrate by etching, deposition or other processes to form a first concave area 401 in the substrate as shown in FIG. 9A and FIG. 9B. FIG. 9A is a top view from the first surface S1 toward the second surface S2, and FIG. 9B is a cross-sectional view along the X direction of FIG. 9A. At least two strips of convex structures 301 are retained in the first concave area 401. A cross-sectional shape of each of the convex structures 301 along a direction parallel to the Z direction may be an arbitrary shape, such as a rectangle, a combined shape of a rectangle and other shapes (e.g. an L shape), etc., which is not limited herein. Projections of two adjacent strips of the at least two strips of convex structures 301 along a direction perpendicular to an extension direction of the convex structures 301 have at least a part non-overlapping areas. In some embodiments, the shapes of two adjacent ones of the convex structures 301 may be different, or all the convex structures 301 in the first concave area 401 may be different. In other embodiments, the shapes of all the convex structures 301 may be the same. However, regardless of the specific shapes of the convex structures 301, and whether the shapes are the same or different from each other, projections of two adjacent ones of the convex structures 301 along a direction perpendicular to an extension direction of the convex structures 301 (i.e. a relatively long side of each of the convex structures 301) have an overlapping area and an non-overlapping area. In the subsequent operations, the shapes of the at least two strips of bit lines formed subsequently are defined by the at least two strips of convex structures 301 located in the first concave area 401.

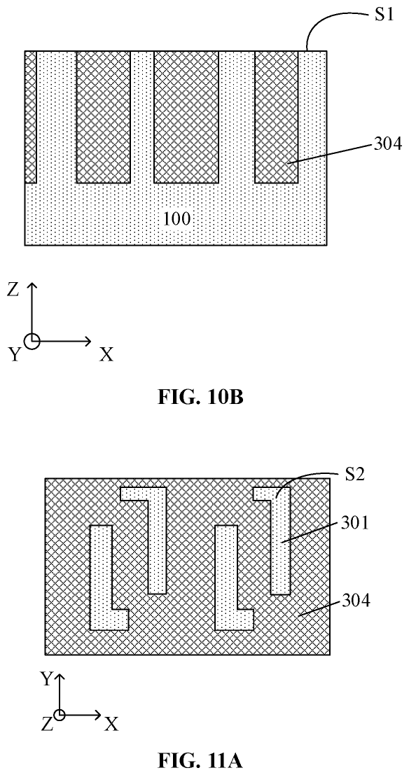

In the above operation S103, the first concave area 401 is filled with an insulating material to form a dielectric layer 304, as shown in FIG. 10A and FIG. 10B. FIG. 10A is a top view from the first surface S1 toward the second surface S2, and FIG. 10B is a cross-sectional view from the X direction of FIG. 10A. The dielectric layer 304 may be formed by filling an insulating material, so that the dielectric layer 304 is present between the at least two strips of convex structures 301. The dielectric layer 304 may be formed by a growth process, for example, in-situ steam generation (ISSG), so as to form the dielectric layer in a selective growth manner. The in-situ vapor generation is a method of thermal annealing deposition, which forms a high-quality oxide film by heating and introducing oxygen atoms in a chamber to combine with atoms in the semiconductor substrate. A deposition process may also be used. The deposition process may include CVD, physical vapor deposition (PVD), plasma enhanced CVD (PECVD), sputtering, metal organic chemical vapor deposition (MOCVD), atomic layer deposition (ALD), or the like.

In some embodiments, the filled insulating material is not only formed between the convex structures 301 but also covers upper surfaces of the convex structures 301. In the case, the insulating material covering the upper surfaces of the convex structures 301 may be processed by a manner including, but not limited to dry etching, wet etching and CMP, until the upper surfaces of the convex structures 301 are exposed again.

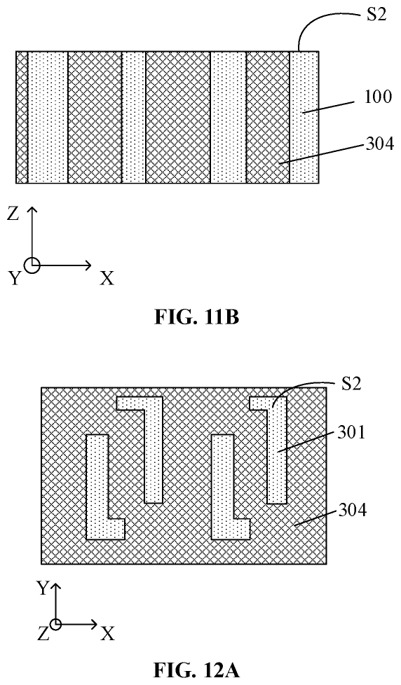

In the above operation S104, the substrate 100 is thinned from a second surface S2 of the substrate 100 until the insulating material is exposed on the second surface S2 as shown in FIG. 11A and FIG. 11B. The second surface S2 is a back surface of the first surface S1. A process of thinning includes, but is not limited to, etching or chemical mechanical polishing (CMP). As shown in FIG. 11A, FIG. 11A is a top view of the thinned substrate from the second surface S2 toward the first surface S1, and FIG. 11B is a cross-sectional view along the X direction in FIG. 11A. After the substrate 100 is thinned from the second surface S2, the dielectric layer 304 is exposed and the convex structures 301 in the dielectric layer 304 may be seen. In some embodiments, after thinning, the dielectric layer 304 is in the same plane as the upper surfaces of the convex structures 301 from the second surface.

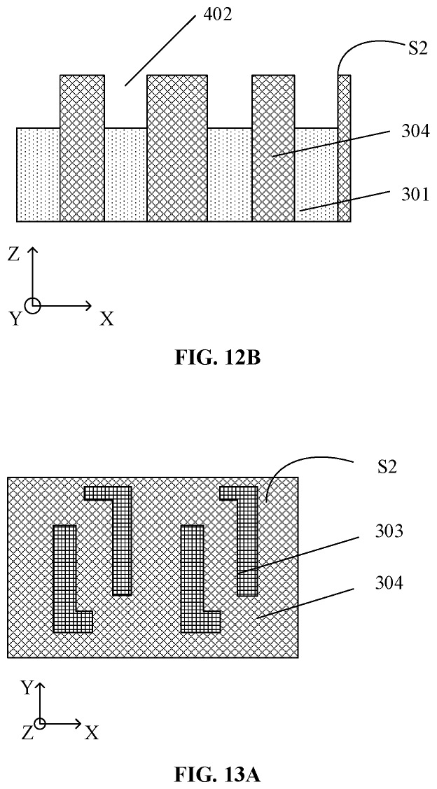

In the above operation S105, each of the convex structures 301 are partially removed from the second surface S2 to form second concave areas 402 as shown in FIG. 12A and FIG. 12B. FIG. 12A is a top view along a direction from the second surface S2 toward the first surface S1, and FIG. 12B is a sectional view along the X direction of FIG. 12A.

Each of the convex structures 301 in the dielectric layer 304 is partially etched along the direction from the second surface S2 to form second concave areas 402 that are recessed relative to the dielectric layer 304. In some embodiments, a part of the convex structures 301 may have conductive channels of the transistors. In other embodiments, a part of the convex structures 301 may be used to form the conductive channels of the transistors in subsequent operations, in which the conductive channels of the transistors may be perpendicular to the thickness direction of the substrate 100.

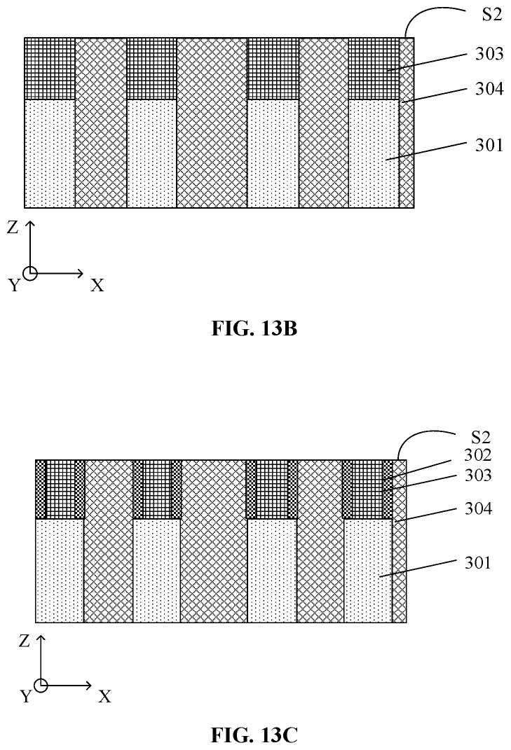

In the above operation S106, a conductive material is filled in the second concave areas 402 to form the bit lines 303 as shown in FIG. 13A and FIG. 13B. FIG. 13A is a top view along a direction from the second surface S2 toward the first surface S1, and FIG. 13B is a cross-sectional view along the X direction in FIG. 13A. The conductive material is filled in the second concave areas 402 by a manner including, but not limited to a growth process or a deposition process. The conductive material includes, but is not limited to, tungsten, cobalt, copper, aluminum, polysilicon (including doped polysilicon), doped silicon, metal silicide (e.g. titanium silicide), or any combination thereof. The bit lines 303 may be made of one or more of the above conductive materials, so that each of the bit lines 303 may be single-layer or multi-layer. The bit lines 303 are formed in the second concave areas 402, and the second concave areas 402 are connected with the convex structures 301. A part of the convex structures 301 may form the conductive channels of the transistors, so that the bit lines 303 may be directly connected with the conductive channels. The bit lines 303 formed in this way do not cause a problem of alignment failure when the bit lines are formed due to the problems of overall warping and local stress of bit line structures to be formed.

In some embodiments, insulating layer 302 may also be formed in the concave areas 402 before the bit lines 303 are formed in the second concave areas 402. As shown in FIG. 13C, the second concave areas 402 have a plurality of opposite sidewalls on which the insulating layers 302 are formed. The insulating layers 302 may be formed by a growth process or a deposition process. The formed insulating layers 302 cover the plurality of sidewalls in the second concave areas 402 and cover at least part of each of the convex structures 301. When the sidewalls of the second concave areas 402 are covered by the insulating layers 302, trenches are formed. The trenches may be filled with a conductive material by a growth process or a deposition process. One or more conductive materials may be used to form each of the bit lines 303. It is beneficial to narrow the size of the bit lines 303 by forming the insulating layers 302 in the second concave areas 402. The insulating layers 302 may be made of silicon dioxide or other insulating material. The material of the insulating layers 302 may be the same as or different from the material of the dielectric layer 304.

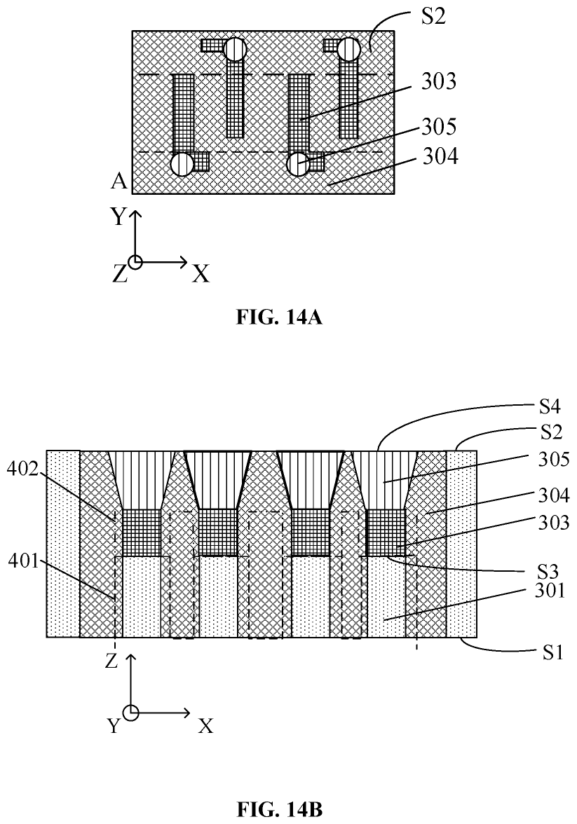

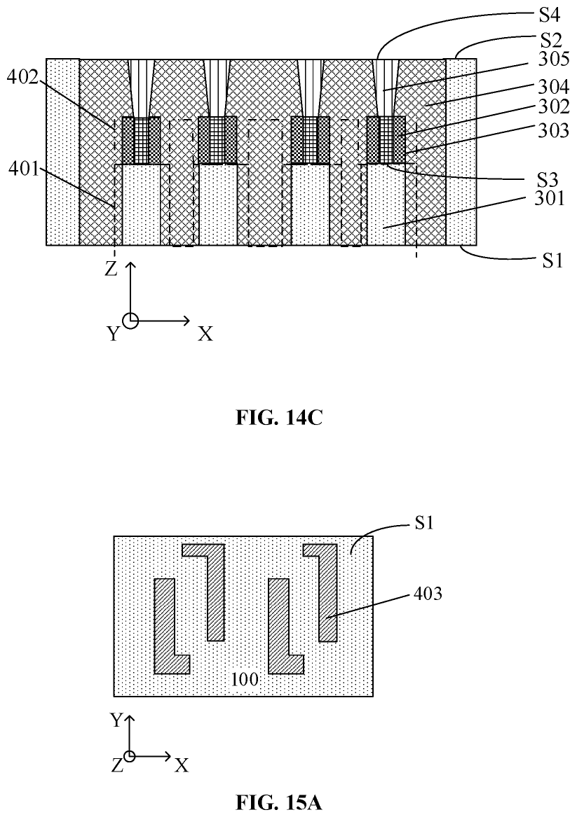

In the above operation S107, the bit line lead-out structures 305 connected with the bit lines 303 are formed at the positions corresponding to the non-overlapping areas on the surfaces of the bit lines 303 as shown in FIG. 14A and FIG. 14B. FIG. 14A is a top view along a direction from the second surface S2 toward the first surface S1, and FIG. 14B is a cross-sectional view along the X direction in FIG. 14A. Since the bit lines 303 are formed on the convex structures 301, the shapes of the bit lines 303 are defined by the shapes of the convex structure 301. Since the projections of two adjacent ones of the convex structures 301 along the direction extending perpendicular to the extension direction of the convex structures 301 have an overlapping area and a non-overlapping area, projections of two adjacent ones of the bit lines 303 along a direction extending along the bit lines 303 (i.e. the distribution direction of the bit lines 303) also have an overlapping area and a non-overlapping area. In some embodiments, the adjacent bit lines 303 form a transistor array in the overlapping area of the projections along the extending direction of the bit lines 303. The bit line lead-out structures 305 connected with the bit lines 303 are formed at the positions corresponding to the non-overlapping area on the surfaces of the bit lines 303. Therefore, the bit line lead-out structures 305 of two adjacent ones of the bit lines 303 are separated by the overlapping areas. The bit line lead-out structures 305 are formed in a peripheral area of the transistor array. It is to be understood that two adjacent ones of the bit line lead-out structures 305 are separated by at least a distance of one transistor array.

In the embodiments of the disclosure, a window distance of two adjacent ones of the bit line lead-out structures 305 is increased effectively. Therefore, it is difficult to short-circuit between the adjacent bit line lead-out structures 305, and the bit line lead-out structures 305 are formed in the peripheral area of the transistor array, which improves an effective utilization of the peripheral area, and thus improves the performance of the device without affecting the space used by the transistor array.

In some embodiments, S102, forming a first concave area 401 from a first surface S1 of the substrate in which at least two strips of convex structures 301 are retained in the first concave area 401 includes the following operations.

In S201, a plurality of first barrier structures 403 are formed on the first surface S1 of the substrate 100.

In S202, a part of the substrate 100 not shielded by the first barrier structures 403 are etched to form the first concave area. A part of the substrate 100 shielded by the first barrier structures 403 are retained as the at least two strips of convex structures 301.

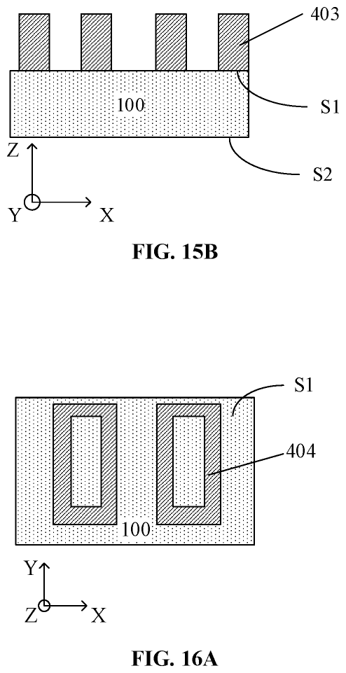

In the above operation S201, a plurality of first barrier structures 403 as shown in FIG. 15A and FIG. 15B are formed on the first surface of the substrate. FIG. 15A is a top view along a direction from the first surface S1 toward the second surface S2, and FIG. 15B is a sectional view along the X direction in FIG. 15A. Different patterns (structures) may be formed on the substrate by using different mask plates combined with lithography processes. The patterns of the first barrier structures 403 may be the same as the patterns of the convex structures 301 to be formed. The material of the substrate 100 has a high etch selectivity ratio with respect to the material forming the first barrier structures 403, that is, only the substrate 100 is etched without damaging to the first barrier structures 403, which is beneficial for the first barrier structures 403 to protect the part of the substrate 100 under the first barrier structures 403). The process of etching may be an anisotropic etching process such that a lateral etching rate is much lower than a longitudinal etching rate, so that the substrate material under the first barrier structures can be retained. The process of etching includes, but is not limited to, dry etching and wet etching.

In the above operation S202, a part of the substrate 100 not shielded by the first barrier structures 403 is etched to form the first concave area 401 as shown in FIG. 9A and FIG. 9B. As shown in FIG. 9B, the part of the substrate 100 shielded by the first barrier structures 403 are retained as the at least two strips of convex structures 301. Since the first barrier structures 403 have protective effect on the substrate 100 thereunder, the part of the substrate 100 covered by the first barrier structures 403 are retained, while the other part of the substrate 100 not protected by the first barrier structures 403 is etched downward to form the first concave area 401. The retained substrate 100 under the first barrier structures 403 is protruding relative to the first concave area 401. It should be noted herein that when the substrate 100 is etched to form the first concave area 401, the substrate 100 should not be etched through, that is, the etching depth is less than the thickness of the substrate 100. If the substrate is etched through in this operation, a plurality of discrete convex structures composed of the remaining substrate 100 will be formed, and the convex structures may collapse due to insufficient support, which is not conducive to the subsequent filling of the insulating material between the convex structures to form the dielectric layer 304.

In some embodiments, S201, forming a plurality of first barrier structures 403 on the first surface S1 of the substrate 100 as shown in FIG. 15A and FIG. 15B includes the following operations.

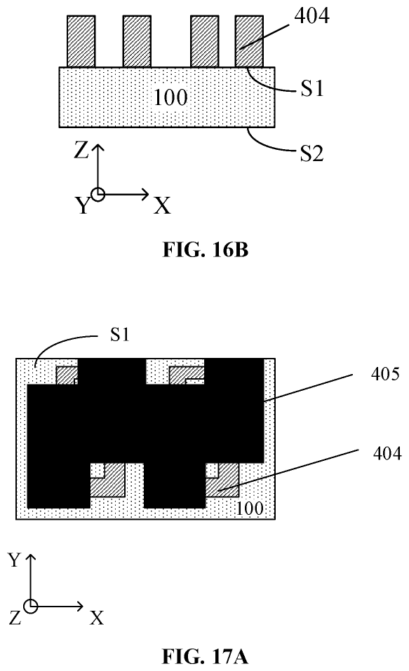

In S301, a plurality of second barrier structures with rectangular annular are formed on the first surface of the substrate as shown in FIG. 16A and FIG. 16B.

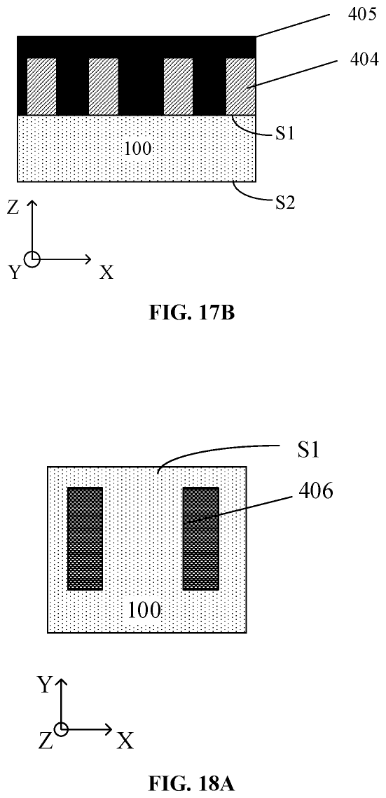

In S302, the plurality of second barrier structures 404 are covered by a first mask layer 405 as shown in FIG. 17A and FIG. 17B, to shield at least partial area of each of the second barrier structures 404. At least two opposite sides of each of the second barrier structures 404 have unshielded areas.

In S303, areas of the second barrier structures 404 unshielded by the first mask layer 405 are etched.

In S304, the first mask layer 405 is removed. Each of the second barrier structures 404 not etched includes two first barrier structures 403.

In some embodiments, as shown in FIG. 15A and FIG. 15B, the shape of each of the first barrier structures 403 is the shape of a corresponding bit line 303 to be formed. For example, if the structure of the bit line 303 to be formed is L-shaped, the first barrier structure 403 is L-shaped.

In some embodiments, the first barrier structures 403 may be formed from the second barrier structures 404, each of which has a rectangular annular shape. In the above operation S301, the plurality of second barrier structures 404 with rectangular annular shape as shown in FIG. 16A and FIG. 16B may be formed on the first surface S1 of the substrate 100. FIG. 16A is a top view along a direction from the first surface S1 toward the second surface S2, and FIG. 16B is a sectional view along the X direction in FIG. 16A.

In the above operation S302, the plurality of second barrier structures 404 are covered by a first mask layer 405 as shown in FIG. 16A and FIG. 16B, to shield at least partial area of each of the second barrier structures 404. At least two opposite sides of each of the second barrier structures 404 with rectangular annular shape have unshielded areas. As shown in FIG. 17A and FIG. 17B, FIG. 17A is a top view along a direction from the first surface S1 toward the second surface S2, and FIG. 17B is a cross-sectional view along the X direction in FIG. 17A.

The pattern of the first mask layer 405 may be irregular, for example, may be of a sawtooth shape. The first mask layer 405 needs to shield at least partial area of each of the second barrier structures 404, so that the shape of the second barrier structure 404 can be changed and the formed first barrier structures 403 differ from the second barrier structures 404. Each of the second barrier structures 404 with rectangular annular shape has two pairs of opposite sides (a pair of long sides and a pair of short sides). In some embodiments, the pair of long sides and/or the pair of short sides have unshielded areas. In some embodiments, the unshielded areas are to be etched. In other embodiments, the shielded areas are to be etched.

In the above operation S303, areas of the second barrier structures 404 unshielded by the first mask layer 405 are etched. The shapes of the second barrier structures 404 is changed to form the shapes of the first barrier structures 403 by etching the unshielded areas of the second barrier structures 404 with rectangular annular shape.

In the above operation S304, the first mask layer 405 is removed. Each of the second barrier structures 404 not etched includes two first barrier structures 403. The first mask layer 405 on the first barrier structures 403 is removed by a process including, but not limited to, dry etching and wet etching, leaving the first barrier structures 403 as shown in FIG. 15A and FIG. 15B. The first mask layer 405 has a high etch selectivity ratio with respect to the first barrier structures 403. A process of etching may be an anisotropic etching process to allow the lateral etching rate being much lower than the longitudinal etching rate, so that the second barrier structures 404 under the first mask layer 405 are retained without changing their shapes due to lateral etching. Each of the second barrier structures 404 not etched is composed of two first barrier structures 403. That is, after the part of the second barrier structure 404 that is not shielded by the first mask layer 405 is etched and the first mask layer 405 is removed, two first barrier structures 403 are retained. Each of the rectangular annular structures is divided into two long sides and two short sides. In some embodiments, each of the first barrier structure 403 is composed of a part of one long side of the rectangular annular structure and/or a part of one short side of the rectangular annular structure, so that the rectangular annular structure may form two first barrier structures 403. The two first barrier structures 403 formed by one rectangular annular structure may be same or different. The first barrier structures 403 formed by different annular structures may be same or different.

In some embodiments, the two first barrier structures 403 included by each of the second barrier structures 404 not etched are centrosymmetric with respect to a center of the second barrier structure.

Each of the second barrier structures 404 with rectangular annular shape has a center which is an intersection of a perpendicular bisector of its long sides and a perpendicular bisector of its short sides. In some embodiments, the two first barrier structures 403 formed by etching one second barrier structure 404 are centrosymmetric to each other about the center.

In some embodiments, each of the second barrier structures 404 may be etched to form two first barrier structures 403 centrosymmetric to each other. The two first barrier structures 403 centrosymmetric to each other are referred to as a first barrier structure group. However, not all the plurality (at least two) of first barrier structure groups formed by the plurality (at least two) of second barrier structures 404 are same.

In some embodiments, each of the first barrier structure groups (e.g. consisting of an L-shape and another L-shape inverted by 180 degrees) formed by the corresponding second barrier structure 404 is identical. Therefore, the bit lines subsequently formed have more regular structures and a more orderly arrangement.

In some embodiments, S301, forming a plurality of second barrier structures 404 with rectangular annular shape on the first surface S1 of the substrate 100, as shown in FIG. 16A and FIG. 16B, includes the following operations.

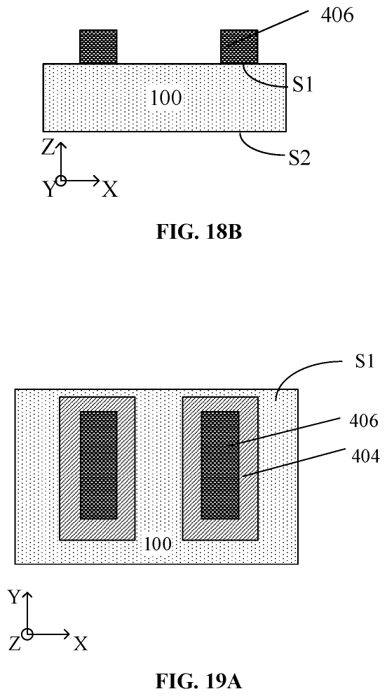

In S401, a plurality of r second mask structures 406 with rectangular shape are formed on the first surface of the substrate as shown in FIG. 18A and FIG. 18B.

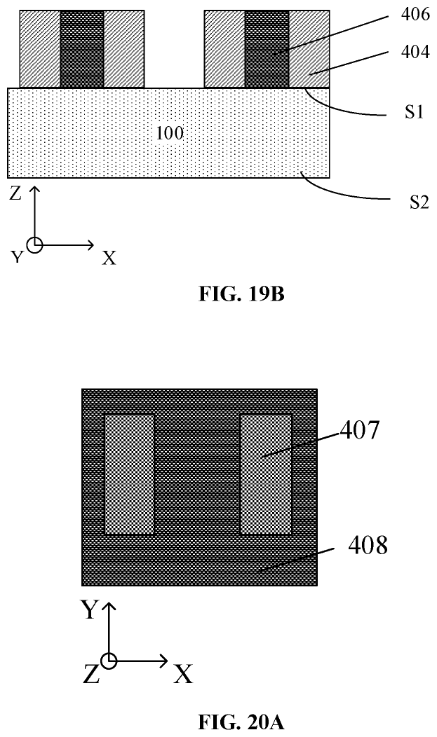

In S402, a second barrier structure 404 surrounding each of the second mask structures 406 as shown in FIG. 19A and FIG. 19B are formed around the second mask structure 406.

In some embodiments, the plurality of second barrier structures 404 with rectangular annular shape may be formed on the first surface S1 of the substrate 100 by the following operations. First, for the above operation S401, a plurality of second mask structures 406 with rectangular shape are formed on the first surface S1 of the substrate 100 as shown in FIG. 18A and FIG. 18B. The second mask structures 406 may be formed by a photolithography process using a patterned mask plate, or may be structures composed of a material having a high etch selectivity ratio with respect to the substrate 100 thereunder. The second mask structures 406 may be of parallelogram structures, or in some embodiments, of rectangular structures.

For the above operation S402, a second barrier structure 404 surrounding each of the second mask structures 406 as shown in FIG. 19A and FIG. 19B are formed around the second mask structure 406. In some embodiments, the second mask structure 406 is a parallelogram with four sidewalls. The annular structure attached to the four sidewalls may be formed on the four sidewalls by a growth process or a deposition process. The annular structure is used to form a second barrier structure. That is, the shape of the second barrier structure 404 is defined by the second mask structure 406. In some embodiments, the second barrier structure 404 is a rectangular annular structure.

In some embodiments, S401, forming a plurality of second mask structures 406 with rectangular shape on the first surface of the substrate, as shown in FIG. 18A and FIG. 18B, includes the following operations.

In S501, the first surface S1 of the substrate 100 is covered by a second mask layer 408.

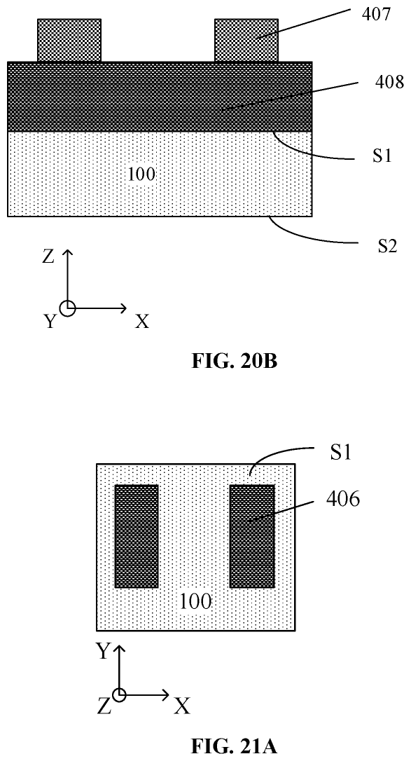

In S502, a photoresist layer 407 with rectangular shapes is formed on the second mask layer as in FIG. 20A and FIG. 20B.

In S503, the second mask layer 408 in an area uncovered by the photoresist layer 407 is removed. The photoresist layer 407 is removed. The second mask layer 408 that has not been removed forms the second mask structures 406.

In some embodiments, forming a plurality of second mask structures 406 with rectangular shapes on the first surface S1 of the substrate 100 may include the following operations. In the above operations S501, the first surface S1 of the substrate 100 is covered by a second mask layer 408, which is used for subsequent formation of the second mask structures 406. It is to be understood that a material of the second mask layer 408 is the same as a material of the second mask structures 406. Unnecessary part of the second mask layer 408 is subsequently etched, and the remaining part is the second mask structures 406.

In the above operation S502, a photoresist layer 407 with rectangular shapes are formed on the second mask layer as shown in FIG. 20A and FIG. 20B. The photoresist layer 407 with rectangular shapes may be formed by a photolithography process. In some embodiments, a photoresist is coated on the second mask layer 408 where the second mask structures 406 are to be formed. A mask plate (the pattern on the mask plate is opaque) is aligned with the photoresist layer. When the photoresist is positive, the exposed part of the photoresist changes from an insoluble substance to a soluble substance. The soluble part can be removed by chemical solvent, so that an island area will leave on the photoresist layer. The island area corresponds to the opaque part of the mask.

The shape of the island area is the shape of the photoresist layer 407. In some embodiments, the shape of the photoresist layer 407 is rectangular. It is to be understood that the photoresist layer 407 with rectangular shape may also be formed using negative photoresist by changing the pattern of the opaque area of the mask correspondingly.

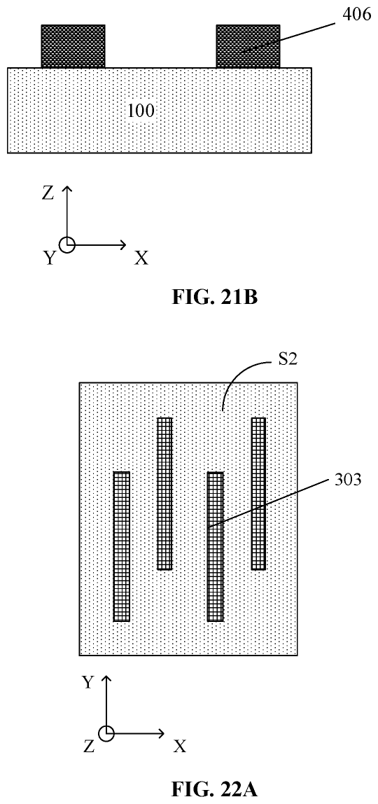

In the above operation S503, the second mask layer 408 in an area uncovered by the photoresist layer 407 is removed. The photoresist layer 407 is removed. The second mask layer 408 that has not been removed forms the second mask structures 406. The second mask structures 406 are formed as shown in FIG. 21A and FIG. 21B. FIG. 21A is a top view along a direction from S1 toward S2, and FIG. 21B is a cross-sectional view along the X direction in FIG. 21A. As shown in FIG. 20B, the photoresist layer 407 cover a part of the second mask layer 408. The part of the second mask layer 408 not covered by the photoresist layer 407 may be removed by a process including but not limited to dry etching and wet etching. The second mask layer 408 has a high etch selectivity ratio with respect to the photoresist layer 407, that is, only the second mask layer 408 is etched without damaging to the photoresist layers 407, which is beneficial for the photoresist layers 407 to protect the part of the second mask layer 408 under the photoresist layers 407. A manner of etching may be an anisotropic etching process which allows a lateral etching rate being much lower than a longitudinal etching rate, so that the second mask layer 408 under the photoresist layer 407 can be retained. As shown in FIG. 18A and FIG. 18B, the shape of the second mask structures 406 (that is, the retained second mask layer 408) is identical to the shape of the photoresist layer 407. In some embodiments, the photoresist layer 407 is rectangular, so the second mask structures 406 (that is, the retained second mask layer 408) are also rectangular.

In some embodiments, the second mask layer 408 may be an amorphous carbon layer and/or a silicon oxynitride layer.

The second mask layer 408 may be a single layer using one material or a multi-layer composite layer using a plurality of materials. In actual formation and etching, the composite layer is regarded as a whole. In some embodiments, the material of the second mask layer may be amorphous carbon and/or silicon oxynitride. That is, the second mask layer 408 may be an amorphous carbon layer and/or a silicon oxynitride layer. When a composite layer of an amorphous carbon layer and a silicon oxynitride layer is used as the second mask layer and the second mask structures are subsequently formed, the second mask structures have a high etch selectivity ratio with respect to the substrate thereunder, and can easily achieve the requirements of vertical rectangular structures and less etching of the substrate.

In some embodiments, the second mask layer 408 may also include a polysilicon layer and/or an oxide layer.

In some embodiments, S104: the method further includes the following operations before thinning the substrate from a second surface of the substrate.

In S601, a carrier wafer 101 is provided.

In S602, the first surface S1 of the substrate 100 is bonded on the carrier wafer 101.

In S603, the substrate 100 is flipped to make the second surface S2 vertically upward.

In some embodiments, the substrate 100 may be directly flipped, so that the second surface S2 of the substrate 100 faces upward and then is thinned. However, it is easy to cause the first surface S1 of the substrate 100 to be damaged.

Therefore, in some embodiments, before thinning the substrate from a second surface of the substrate, the above operation S104 may further include the following operations.

In some embodiments, before the second surface S2 of the substrate is thinned, the first surface S1 of the substrate may be fixed to a supporting structure to prevent a structure of the transistor array that has been formed from being damaged when the second surface S2 of the substrate is thinned. The supporting structure may be a carrier wafer, so S601 may be performed in which the carrier wafer 101 is provided. The carrier wafer 101 may be made of the same material as the substrate 100. For example, when the substrate 100 is a silicon substrate, the carrier wafer 101 may be a silicon wafer. Next, S602 is performed, in which the first surface S1 of the substrate 100 is bonded on the carrier wafer 101. At the time, the second surface S2 is still adown. Since the second surface S2 needs to be processed subsequently, S603 may be performed in which the substrate 100 is flipped to make the second surface S2 vertically upward, which facilitates the thinning process from the second surface S2 in the subsequent operation S104.

The embodiments of the disclosure also provide a semiconductor structure, as shown in FIG. 14A and FIG. 14B, which includes a substrate 100, a first concave area 401, a dielectric layer 304, second concave areas 402, bit lines 303 and bit line lead-out structures 305.

The first concave area 401 is on a first surface S1 of the substrate 100. At least two strips of convex structures 301 are retained in the first concave area 401. Projections of two adjacent strips of the at least two strips of convex structures 301 along a direction perpendicular to an extension direction of the convex structures 301 have at least a part non-overlapping areas.

The dielectric layer 304 is located in the first concave area.

The second concave areas 402 are located on the second surface S2 of the substrate 100 and in the dielectric layer 304.

Each of the bit lines 303 is in a corresponding one of the second concave areas 402 and composed of a conductive material.

Each of the bit line lead-out structures 305 is connected with a corresponding one of the bit lines 303 at a corresponding non-overlapping area on a surface of the bit line 303.

As shown in FIG. 14A and FIG. 14B, FIG. 14A is a top view of a semiconductor structure, and FIG. 14B is a front view of the semiconductor structure along the X direction.

The semiconductor substrate 100 has a certain thickness, so that it has a first surface S1 and a second surface S2 opposite to each other. It is to be seen from the first surface S1 that, the substrate has a first concave area 401 and there is at least two strips of convex structures 301 in the first concave area 401. Each of the convex structures 301 may be used to subsequently form conductive channels of at least one transistor array. The transistor array is used to implement functions of data storage, reading and writing. At least one conductive channel formed by the same convex structure 301 is referred to as a conductive channel group. The first concave area 401 may have a dielectric layer 304 formed of an insulating material. Different conductive channel groups are separated by the dielectric layer 304.

It is to be seen from the second surface S2 toward the first surface S1 that, the substrate 100 has second concave areas 402. The second concave areas 402 are in the dielectric layer 304, that is, the dielectric layer 304 is higher than the second concave areas 402. The convex structures 301 are below the second concave areas 402.

It can be seen from the second surface S2 towards the first surface S1 that, there are also bit lines 303 on the convex structures 301, that is, in the second concave areas 402. The bit lines are composed of a conductive material.

In some embodiments, a cross-sectional view of one of the convex structures 301 in the first concave area 401 along the Z direction is the same as a cross-sectional view of the corresponding bit line 303 along the Z direction.

Therefore, when projections of two adjacent strips of the at least two strips of convex structures 301 along a direction perpendicular to an extension direction of the convex structures 301 have at least a part non-overlapping areas, projections of two adjacent ones of the bit lines 303 along a direction perpendicular to an extension direction of the bit lines 303 (i.e. the distribution direction of the bit lines 303) also have at least a part non-overlapping areas.

The bit lines 303 are located in the second concave areas 402 formed by the dielectric layer 304, and the second concave areas 402 are connected with the convex structures 301, so that the bit lines 303 are closely connected with the convex structures 301. There may be conductive channels in the convex structures 301, so that the bit lines 303 may be closely connected with the conductive channels.

In some embodiments, there may also be insulating layers 302 in the second concave areas 402 as shown in FIG. 14C. The insulating layers 302 cover a plurality of sidewalls in the second concave areas 402 and cover at least a part of each of the convex structures 301, to form trenches with sidewalls covered by the insulating layers 302. It is to be understood that an opening of each of the trenches is smaller than an opening of the corresponding second concave area 402. The insulating layers 302 may be made of silica or other insulating material. The material of the insulating layers 302 may be the same as or different from the material of the dielectric layer 304.

When the sidewalls of the second concave areas 402 are covered with the insulating layers 302, the second concave areas 402 become the trenches. The trenches are filled with a conductive material. One or more conductive materials may be used to form the bit lines 303. For example, in some embodiments, one conductive material may be used to fill the trenches until it is flush with first ends of the conductive channels. For another example, in some embodiments, the trenches may be filled with three conductive materials successively until the conductive materials are flush with the first ends of the conductive channels. A width of openings of the trenches is a first width of the exposed first ends of the conductive channels. The conductive material includes but not limited to tungsten, cobalt, copper, aluminum, polysilicon, doped silicon, silicide, or any combination thereof. Therefore, each of the bit lines 303 may also include a single film layer (using a conductive material) or a plurality of film layers (using a plurality of conductive materials), which is not limited by the disclosure. The plurality of bit lines 303 are formed based on a plurality of vertical bar structures staggered up and down, that is, the shapes of the plurality of bit lines are also vertical bar structures staggered up and down.

In some embodiments, the projections of two adjacent strips of the bit lines 303 along a direction perpendicular to the extension direction of the bit lines 303 have at least partial overlapping areas, so the projections of the adjacent bit lines 303 along an extension direction of the bit lines also have an overlapping area and a non-overlapping area. In some embodiments, there is a transistor array in the overlapping area of the projections of two adjacent ones of the bit lines 303 along the extension direction of the bit lines 303 and the overlapping area of the semiconductor structure having the bit lines along the extension direction of the bit lines 303. The bit line lead-out structures 305 connected with the bit lines 303 are present at the positions corresponding to the non-overlapping areas on the surfaces of the bit lines 303. Therefore, the bit line lead-out structures 305 of two adjacent ones of the bit lines 303 are separated by the overlapping areas. The bit line lead-out structures 305 are formed in a peripheral area of the transistor array. It is to be understood that two adjacent ones of the bit line lead-out structures 305 are separated by at least a distance of one transistor array.

In some embodiments, the transistor array may be of a vertical channel array transistor (VCAT) architecture, and may also be architecture of planar transistor (Planar) or buried channel array transistor (BCAT). Compared with the architecture of BCAT, the architecture of VCAT has higher storage density. Sources and drains of transistors in VCAT are located at upper and lower ends of the vertical channel areas. In a process for forming a semiconductor device, bit lines or other structures may be respectively arranged in two opposite surfaces of a wafer by combining a wafer bonding technology and a back thinning technology. For example, for dynamic random access memory (DRAM), bit lines and capacitors of DRAM storage array may be respectively arranged on two sides of a same wafer, so that circuit arrangement of word lines, bit lines and capacitors can be simplified and difficulty of a manufacturing process of semiconductor devices can be reduced.

In the embodiments of the disclosure, the window distance between the bit line lead-out structures 305 is increased effectively by arranging the bit line lead-out structures 305 in the non-overlapping areas of the adjacent bit lines 303 along the distribution direction of the bit lines. Therefore, it is difficult to short-circuit between the bit line lead-out structures 305, and the bit line lead-out structures 305 are formed in the peripheral area of a transistor array, which improves an effective utilization of the peripheral area, and thus improves the performance of the device without affecting the space used by the original transistor array.

In some embodiments, as shown in FIG. 14B, each of the bit line lead-out structures 305 has a third surface S3 and a fourth surface S4 opposite to each other. The third surface S3 is connected with a corresponding one of the bit lines 303. An area of the fourth surface S4 is larger than an area of the third surface S3.

The bit line lead-out structures 305 are present on the non-overlapping areas of the adjacent bit lines 303. Each of the bit line lead-out structures 305 has the third surface S3 and the fourth surface S4 opposite to each other. The third surface S3 is connected with a bit line 303. In some embodiments, an area of the third surface S3 connected with the bit line 303 (a cross-sectional area along the direction parallel to the first surface) is smaller than an area of the fourth surface S4 (a cross-sectional area along the direction parallel to the first surface), so that the bit line lead-out structure 305 has a larger contact area to connect other structures, which is beneficial to electrifying the bit line. The shapes of the third surface S3 and the fourth surface S4 may be circular, elliptical, rectangular, etc., which is not limited herein.

In some embodiments, two adjacent ones of the bit lines 303 are centrosymmetric as shown in FIG. 14A.

In some embodiments, two adjacent ones of the bit lines 303 are centrosymmetric. A plurality of such bit lines 303 are more regular and arranged in a more orderly way. Thus, the bit line lead-out structures 305 formed at the non-overlapping areas of the adjacent bit lines 303 are also more regular and ordered.

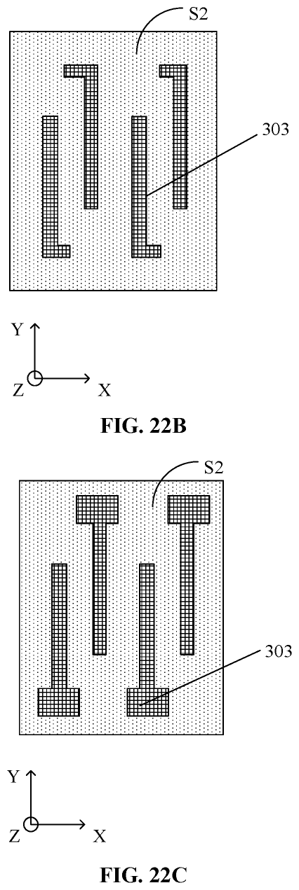

In some embodiments, as shown in FIG. 22A, the bit lines 303 may be of vertical bar shapes staggered up and down. As shown in FIG. 22B, the bit lines 303 may be of L-shapes and L-shapes inverted by 180 degrees staggered up and down. As shown in FIG. 22C, the bit line 303 may be of T-shapes and T-shapes inverted by 180 degrees staggered up and down.

The embodiments of the disclosure also provide the following example.

In some embodiments, the bit line lead-out structures 305 may be formed by the following operations.

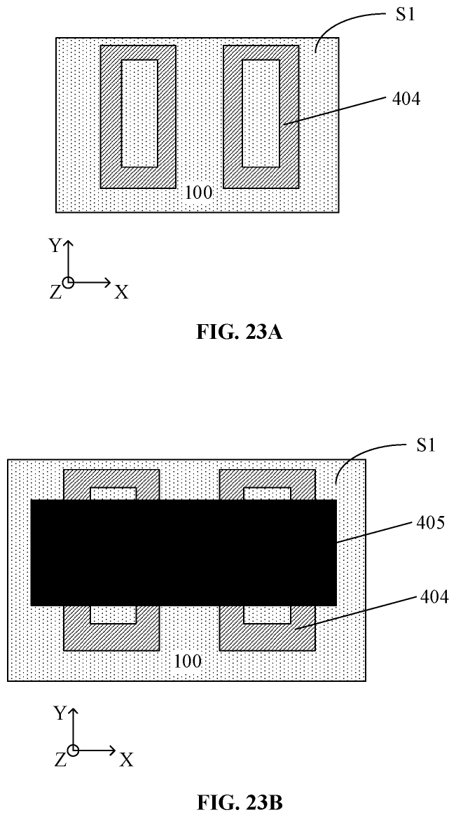

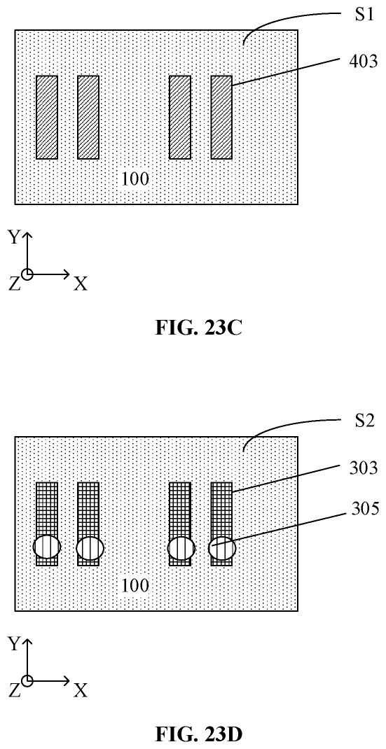

The second barrier structures 404 with rectangular annular shape as shown in FIG. 23A are formed on the substrate 100 in the following way. Second mask structures 406 with rectangular shapes are first formed on the substrate 100 by a photolithography process. Silicon oxide is then deposited on four sidewalls of the second mask structures 406 with rectangular shapes by an ALD process to form the second barrier structures 404 with rectangular annular shapes. The second mask structures 406 with rectangular shapes are then removed by etching. The second barrier structures 404 with rectangular annular shapes are reserved.

The second barrier structures 404 with rectangular annular shapes are then processed using a photolithography process. A specific processing way may include the following operations. A photoresist layer is coated on the second barrier structure 404 with rectangular annular shapes. A first mask layer 405 with an opaque rectangular pattern as shown in FIG. 23B is aligned with the photoresist layer, and a photoresist is exposed. The photoresist used is positive, and a part under an opaque rectangular pattern of the first mask layer 405 will be retained. When the photoresist layer is removed, a part of the second barrier structures overlapped with the part of the opaque rectangular pattern is retained, so as to form a plurality of first barrier structures 403 as shown in FIG. 23C. The plurality of first barrier structures 403 are in shapes of vertical bar structures. Projections of the plurality of first barrier structures 403 along a direction perpendicular to their extension direction all overlap. There is no area where the projections of two adjacent ones of the first barrier structures 403 along a direction perpendicular to their extension direction do not overlap.

The plurality of bit lines 303 are formed based on the plurality of first barrier structures 403. In some embodiments, active areas of the second surface S2 of the substrate 100 are etched as a whole, to expose the first barrier structures 403. The first barrier structures 403 are further etched to form the second concave areas 402, and then the bit lines 303 are formed in the second concave areas 402. It is to be seen that the window distance left for the bit line lead-out structures 305 is very small and only a plurality of bit line lead-out structure 305 as shown in FIG. 23D may be formed.

The adjacent bit line lead-out structures 305 formed in this way are prone to short circuit, and even lead to the failure of the semiconductor device.

In some embodiments, the bit line lead-out structures 305 may also be formed by the following operations.

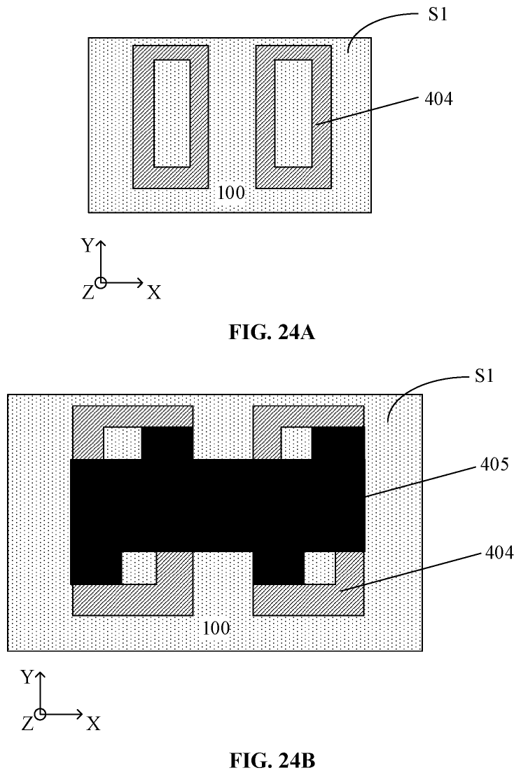

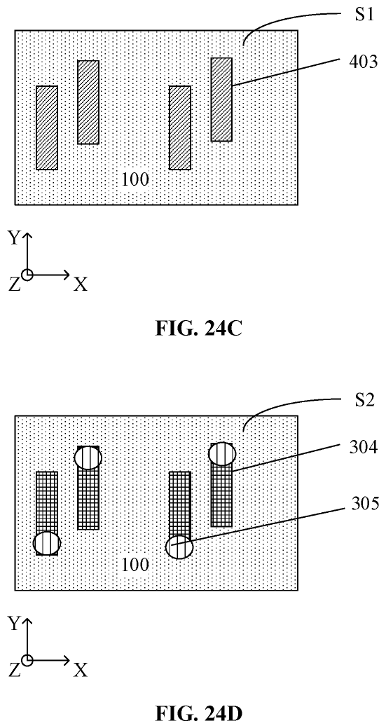

The second barrier structures 404 with rectangular annular shapes as shown in FIG. 24A are formed on the substrate 100 in the following way. Second mask structures 406 with rectangular shapes are first formed on the substrate 100 by a photolithography process. Silicon oxide is then deposited on four sidewalls of the second mask structures 406 with rectangular shapes by an ALD process to form second barrier structures 404 with rectangular annular shapes. The second mask structures 406 with rectangular shapes are then removed by etching. The second barrier structures 404 with rectangular annular shapes are reserved.

The second barrier structures 404 with rectangular annular shapes are then processed using a photolithography process. A specific processing way may include the following operations. A photoresist layer is coated on the second barrier structures 404 with rectangular annular shapes. A first mask layer 405 with a sawtooth shape that is opaque and is concave and convex with respect to the rectangle as shown in FIG. 24B is aligned with the photoresist layer, and the photoresist is exposed. The photoresist used is positive, and a part under an opaque rectangular pattern of the first mask layer 405 will be retained. When the photoresist layer is removed, a part of the second barrier structures overlapped with the part of the opaque rectangular pattern is retained, and a plurality of first barrier structures 403 are formed as shown in FIG. 24C. The plurality of first barrier structures 403 are in shapes of vertical bar structures staggered up and down. Projections of two adjacent ones of the first barrier structures 403 along a direction perpendicular to their extension direction have an overlapping area and a non-overlapping area.

It is to be understood that the shape of the first mask layer 405 is not limited to a sawtooth shape that is concave and convex with respect to the rectangle. The shape of the first mask layer 405 may be changed according to the shape of the first barrier structure.

The first concave area 401 is formed on the first surface of the substrate 100 based on the plurality of first barrier structures 403. At least two strips of convex structures 301 are retained in the first concave area 401. Projections of two adjacent strips of the at least two strips of convex structures 301 along a direction perpendicular to an extension direction of the convex structures 301 have at least a part non-overlapping areas. The first concave area 401 is filled with the insulating material to form the dielectric layer 304.

The substrate 100 is then thinned from the second surface S2 of the substrate 100 until the dielectric layer is exposed on the second surface. Each of the convex structures continues to be partially removed from the second surface S2 of the substrate 100 to form the second concave area 402. The second concave areas 402 are filled with the conductive material to form the bit lines 303. Therefore, the shapes of the plurality of bit lines 303 are formed based on the shapes of the plurality of first barrier structures 403.

The bit line lead-out structures 305 are formed at the positions corresponding to the non-overlapping areas on the surfaces of the bit lines 303 as shown in FIG. 24D. Therefore, the bit line lead-out structures 305 of two adjacent bit lines are separated by the overlapping area between the adjacent bit lines. A transistor array may be formed in the overlapping area. That is, the lead-out structures are formed in the peripheral area of the transistor array. It is to be understood that two adjacent ones of the bit line lead-out structures 305 are separated by at least a distance of one transistor array. Therefore, the window distance between the bit line lead-out structures 305 is increased effectively in the semiconductor structure formed by embodiments of the disclosure, which makes it difficult to short-circuit between the bit line lead-out structures 305 and effectively ensures the service performance of the device.

It is to be understood that “an embodiment” or “some embodiments” referred to throughout the specification mean that particular features, structures or characteristics related with the embodiments are included in at least one embodiment of the disclosure. Therefore, the phrases “in an embodiment” or “in some embodiments” appearing throughout the specification do not necessarily refer to a same embodiments. In addition, these particular features, structures or characteristics may be incorporated in one or more embodiments in any suitable manner. It is to be understood that in the various embodiments of the disclosure, the size of the serial numbers of the above-mentioned processes does not mean the sequence of execution, and the execution sequence of each process should be determined by its function and inherent logic, and should not constitute any limitation on the implementation process of the embodiments of the disclosure. The above reference numerals of the embodiments in this disclosure are for description only, and do not represent the advantages and disadvantages of the embodiments.

It is to be noted that, in the disclosure, the terms “include”, “comprise” or any other variation thereof are intended to encompass non-exclusive inclusion, so that a process, method, article or device that includes a set of elements includes not only those elements, but also other elements that are not explicitly listed, or also elements inherent to such a process, method, article or device. In the absence of further limitations, an element defined by the phrase “include/comprise a . . . ” does not exclude existence of another identical element in the process, method, article or device including the element.

The above-mentioned are only some embodiments of the disclosure, and the protection scope of the disclosure is not limited thereto. Within the technical scope of the disclosure, any skilled person familiar with the technical field may easily conceive of changes or substitutions, which should fall within the protection scope of the disclosure. Therefore, the scope of protection of this disclosure shall be subject to the scope of protection of the claims.

### INDUSTRIAL PRACTICALITY

In the embodiments of the disclosure, a window distance of the adjacent two of the bit line lead-out structures is increased effectively by setting the bit line lead-out structures in the non-overlapping areas of the adjacent bit lines along the extending direction of the bit lines. Therefore, it is difficult to short-circuit between the adjacent bit line lead-out structures, and the bit line lead-out structures are formed in the peripheral area of a transistor array, which improves an effective utilization rate of the peripheral area and thus improves performance of the device without affecting the space used by the transistor array.

1. A method for manufacturing a semiconductor structure, comprising:
providing a substrate;
forming a first concave area from a first surface of the substrate, at least two strips of convex structures being retained in the first concave area; projections of two adjacent strips of the at least two strips of convex structures along a direction perpendicular to an extension direction of the convex structures having at least a part non-overlapping areas:
filling the first concave area with an insulating material to form a dielectric layer;
thinning the substrate from a second surface of the substrate until the dielectric layer is exposed on the second surface, wherein the second surface is a back surface of the first surface;
partially removing each of the convex structures from the second surface to form a second concave area;
filling a conductive material in the second concave area to form a bit line; and
forming a bit line lead-out structure connected with the bit line at a position corresponding to the non-overlapping area on a surface of the bit line.

2. The method of claim 1, wherein forming a first concave area from a first surface of the substrate, at least two strips of convex structures being retained in the first concave area comprises:
forming a plurality of first barrier structures on the first surface of the substrate; and
etching a part of the substrate not shielded by the first barrier structures to form the first concave area, wherein a part of the substrate shielded by the first barrier structures is retained as the at least two strips of convex structures.

3. The method of claim 2, wherein forming a plurality of first barrier structures on the first surface of the substrate comprises:
forming a plurality of second barrier structures with rectangular annular shape on the first surface of the substrate:
covering the plurality of second barrier structures by a first mask layer to shield at least partial area of each of the plurality of second barrier structures: wherein at least two opposite sides of each of the plurality of second barrier structures have unshielded areas:
etching areas of the plurality of second barrier structures unshielded by the first mask layer; and
removing the first mask layer, wherein each of the plurality of second barrier structures not etched comprises two of the first barrier structures.

4. The method of claim 3, wherein the two first barrier structures comprised in each of the plurality of second barrier structures not etched are centrosymmetric with respect to a center of the second barrier structure.

5. The method of claim 3, wherein forming a plurality of second barrier structures with rectangular annular shape on the first surface of the substrate comprises:
forming a plurality of second mask structures with rectangular shape on the first surface of the substrate; and
forming a second barrier structure surrounding each of the plurality of second mask structures.

6. The method of claim 5, wherein forming a plurality of second mask structures with rectangular shape on the first surface of the substrate comprises:
covering the first surface of the substrate by a second mask layer:
forming a photoresist layer with rectangular shapes on the second mask layer;
removing the second mask layer in an area uncovered by the photoresist layer; and removing the photoresist layer, wherein the second mask layer that has not been removed forms the second mask structures.

7. The method of claim 1, before thinning the substrate from a second surface of the substrate, further comprising:
providing a carrier wafer;
bonding the first surface of the substrate on the carrier wafer; and
flipping the substrate to make the second surface vertically upward.

8. A semiconductor structure, comprising:
a substrate;
a first concave area on a first surface of the substrate; at least two strips of convex structures being retained in the first concave area, and projections of two adjacent strips of the at least two strips of convex structures along a direction perpendicular to an extension direction of the convex structures having at least a part non-overlapping areas;
a dielectric layer in the first concave area;
second concave areas on a second surface of the substrate and in the dielectric layer;
bit lines, each of the bit lines being located in a corresponding one of the second concave areas and composed of a conductive material; and
bit line lead-out structures, each of the bit line lead-out structures being located on a surface of a corresponding one of the bit lines corresponding the non-overlapping area and connected with the bit line.

9. The semiconductor structure of claim 8, wherein each of the bit line lead-out structures has a third surface and a fourth surface opposite to each other, the third surface is connected with the corresponding bit line, and an area of the fourth surface is larger than an area of the third surface.

10. The semiconductor structure of claim 8, wherein two adjacent ones of the bit lines are centrosymmetric.
